(19) United States
(12) Patent Application Publication
(10) Pub. No.: US 2014/0291826 A1
(43) Pub. Date: Oct. 2, 2014

(54) SEMICONDUCTOR DEVICE MANUFACTURING METHOD AND SEMICONDUCTOR DEVICE

(71) Applicant: Renesas Electronics Corporation, Kanagawa (JP)

(72) Inventor: Motoi ISHIDA, Kanagawa (JP)

(73) Assignee: RENESAS ELECTRONICS CORPORATION, Kanagawa (JP)

(21) Appl. No.: 14/219,813

(22) Filed: Mar. 19, 2014

(30) Foreign Application Priority Data
Apr. 2, 2013 (JP) 2013-076787

(51) Int. Cl. H01L 23/49; H01L 23/495; H01L 23/00

(52) U.S. Cl. CPC H01L 23/49; H01L 24/96; H01L 23/49541
USPC 257/676; 438/123

(57) ABSTRACT

A semiconductor device and a manufacturing method for a semiconductor device in which during QFP (quad flat package assembly) a wire passing over a bus bar and coupled to an inner lead is set at a loop height different from a second wire at a low loop height, and a third wire at a high loop height, and also mounted nearer a standard suspension lead than the second wire and the third wire. The loop height of the wire becomes gradually higher than the direction of resin flow in the resin sealing process so that wire sweep can be reduced and the reliability of the QFP assembly can be improved.

### CROSS-REFERENCE TO RELATED APPLICATIONS

The disclosure of Japanese Patent Application No. 2013-076787 filed on Apr. 2, 2013 including the specification, drawing and abstract is incorporated herein by reference in its entirety.

### BACKGROUND

The present invention relates to manufacturing technology for a semiconductor device and to a semiconductor device, and relates in particular for example to technology that is applicable to semiconductor devices containing for example a bus bar (common lead).

A technology is disclosed in Japanese Unexamined Patent Application Publication No. 2010-186831 for a structure in which a first bus bar and a second bus bar are respectively mounted between a lead group mounted at an outer circumferential section and a bed section where a semiconductor chip is mounted; and the first bus bar is mounted at the same height as the bed section, and the second bus bar is mounted at the same height as an inner lead section, and a wire is coupled at different heights to each bus bar and the inner lead section.

A technology is disclosed in Japanese Unexamined Patent Application Publication No. Hei9 (1997)-266223 for a structure in which the loop height for long wires differ by levels, and the loop heights are different in levels from the center of the semiconductor chip towards the periphery.

### SUMMARY

There is an increasing need to make semiconductor devices (package) smaller in size. Reducing the number of terminal (external terminals, outer leads) is required to achieve a smaller size. One measure to achieve fewer terminals is employing a known technology where the ground sections are bundled together with a die pad and wire bonding (ground bonding) is performed, and a bus bar having lead terminals joined together within the package is utilized for the power supply sections. In this way the number of terminal can be reduced.

However, in technology utilizing ground bonding and bus bars, wire bonding is performed plural times (plural levels) by bundling the ground sections and power supply sections together, and wire sweep (ratio of wire deviation to wire span that applies stress leading to breakage or weakening of bond point) is no longer uniform due to the resin pressure during resin sealing. Consequently electrical wiring shorts tend to easily occur so that providing a stable manufacturing technology is needed.

One known technology for reducing electrical wiring shorts is to extend the bus bar containing the joined lead terminals more towards the die pad side than the inner lead, and mounting the bus bar at a position lower than the upper surface of the tip of the inner lead. This technology is capable of securing the gaps between wires of different lengths and preventing electrical wiring shorts.

However, in this technology the bus bar is processed into a bend forming during forming of the lead frame in order to make the bus bar height at a position lower than the tip of the inner lead. However a space is needed on the periphery of the bus bar for mounting the metal mold that forms the bend in the bus bar, which required shortening the inner leads surrounding the bus bar, or shortening the adjacent inner leads towards the outer circumferential section of the package.

Consequently, the problem occurred that the length of the bonding wire passing over the bus bar became long, and the long length of this wire caused a large wire sweep during resin sealing thus increasing the probability of electrical wiring shorts occurring.

An objective for implementing the embodiments described in the present specifications is to provide technology capable of improving the reliability of the assembly the semiconductor device.

Other novel features and other issues will become readily apparent from the description in these specifications and the accompanying drawings.

According to an aspect of the invention, the manufacturing method for a semiconductor device includes a process to electrically couple the leads and the electrode pad of the semiconductor chip by wires and in which, an electrode pad and a first lead are coupled by a first wire, an electrode pad and any of the second leads are coupled by a second wire, and an electrode pad and any of the another second leads are coupled by a third wire at a loop height higher than the second wire. Further, in the manufacturing method of the above described semiconductor device, the second wire is mounted nearer than the third wire relative to a standard suspension lead corresponding to a position of gate for supplying resin among the plural suspension leads.

According to the aspect of the invention, the reliability of the assembly of the semiconductor device may be improved.

### BRIEF DESCRIPTION OF THE DRAWINGS

FIG. 1 is a plan view showing an example of the structure of the semiconductor device of the embodiment;

FIG. 2 is a plan view showing the structure of the semiconductor device in FIG. 1 after passage of a sealing body (sealing resin);

FIG. 3 is a cross-sectional view showing the structure divided along the lines A-A shown in FIG. 2;

FIG. 4 is a cross-sectional view showing the structure divided along the lines B-B shown in FIG. 2;

FIG. 5 is a fragmentary enlarged plan view showing an example of the wiring status in the semiconductor structure shown in FIG. 1:

FIG. 6 is a fragmentary enlarged cross-sectional view showing the structure divided along the lines A-A shown in FIG. 5;

FIG. 7 is a fragmentary plan view showing an example of the structure of the lead frame utilized in the assembly of the semiconductor device shown in FIG. 1;

FIG. 8 is a fragmentary enlarged plan view showing an enlargement of the C section shown in FIG. 7:

FIG. 9 is a fragmentary plan view showing an example of the structure after die bonding during the assembly of the semiconductor device shown in FIG. 1;

FIG. 10 is a fragmentary plan view showing an example of the structure after wire bonding during the assembly of the semiconductor device shown in FIG. 1;

FIG. 11 is a fragmentary cross-sectional view showing the structure divided along the lines A-A shown in FIG. 10;

FIG. 12 is a fragmentary cross-sectional view showing the structure divided along the lines B-B shown in FIG. 10;

FIG. 13 is a fragmentary cross-sectional view showing an example of the structure during resin molding in the assembly of the semiconductor device shown in FIG. 1;

FIG. 14 is a fragmentary cross-sectional view showing an example of the structure after resin molding in the assembly of the semiconductor device shown in FIG. 1;

FIG. 15 is a fragmentary cross-sectional view showing an example of the structure during cutting and molding in the assembly of the semiconductor device shown in FIG. 1;

FIG. 16 is a cross-sectional view showing the structure of the semiconductor device in an adaptation of the embodiment.

### DETAILED DESCRIPTION

In the following embodiments, descriptions of the same or identical sections are generally not repeated except where necessary.

Also when necessary for purposes of convenience in the following embodiments, the description is given while separated into plural sections or embodiments however unless specified otherwise these sections are not mutually unrelated, and one section may be a part of another or all of the adaptations, detailed descriptions, and supplementary descriptions may be related.

Moreover, in the following embodiments, when describing the number of elements (including the number of pieces, numerical value, quantity, range, etc.) unless clearly specified otherwise, and except for cases where clearly and fundamentally limited to a designated number, there is no particular limit on a designated number and a number above or a number below the designated number is acceptable.

Needless to say, in the following embodiments, unless specifically designated otherwise and where clearly fundamentally required, the structural elements (including the element steps, etc.) are not always necessary.

Also needless to say in the following embodiments, when the phrase “comprised of A” “configured from A” “containing A” “including A” is expressed for the structural elements, the description is not exclusive of other elements, except for cases where the description is specifically limited to just those elements. When the shape of structural elements and so on, and the positional relationship and so on are expressed in the following description, other elements substantially approximating or resembling those shapes are included except for cases where clearly specified otherwise and cases where clearly and fundamentally to the contrary. This state also applies to the above mentioned number and ranges, etc.

The embodiments are hereafter described while referring to the drawings. In all of the drawings for describing the embodiments, member having identical functions are assigned the same reference numerals, and a redundant description is omitted. Also, to make the drawings easier to understand hatching has been added in some cases even to the plan drawings.

### Embodiment

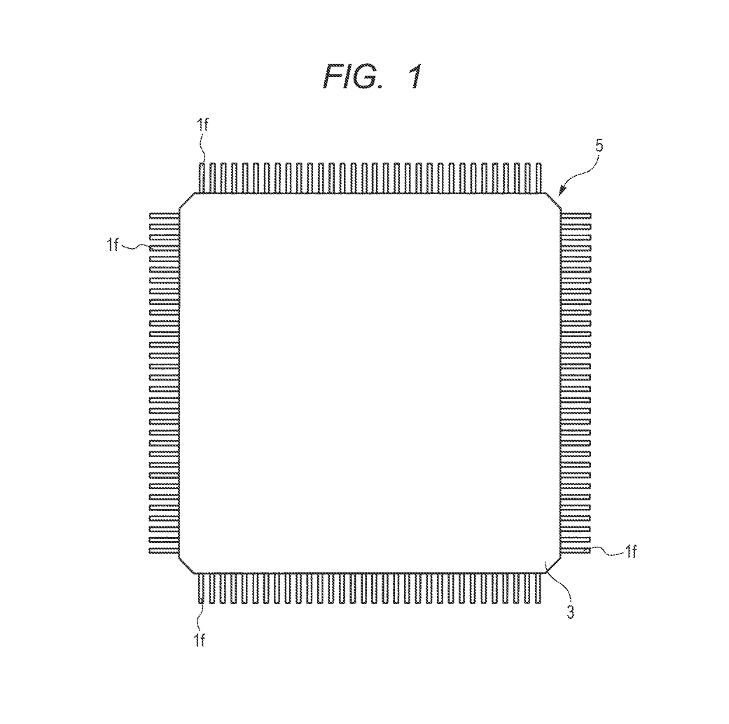

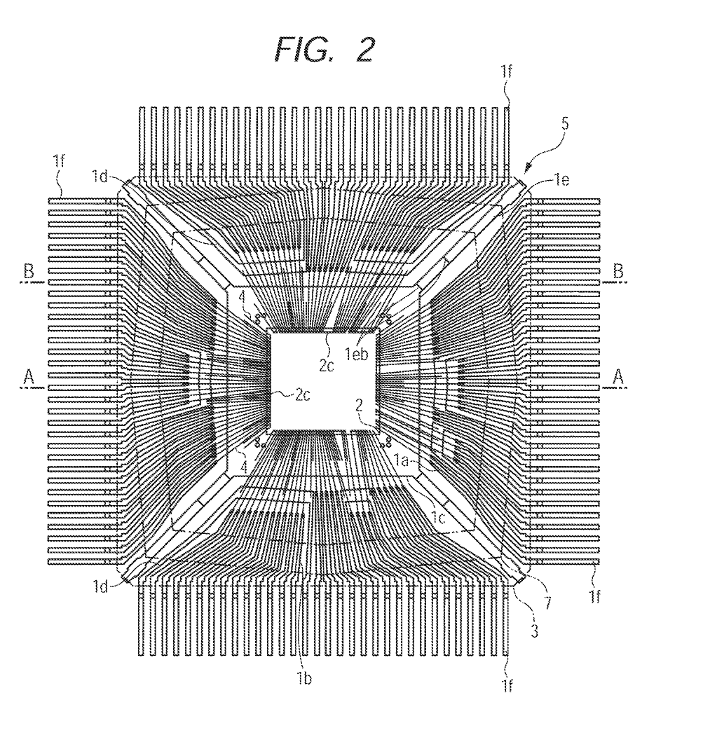

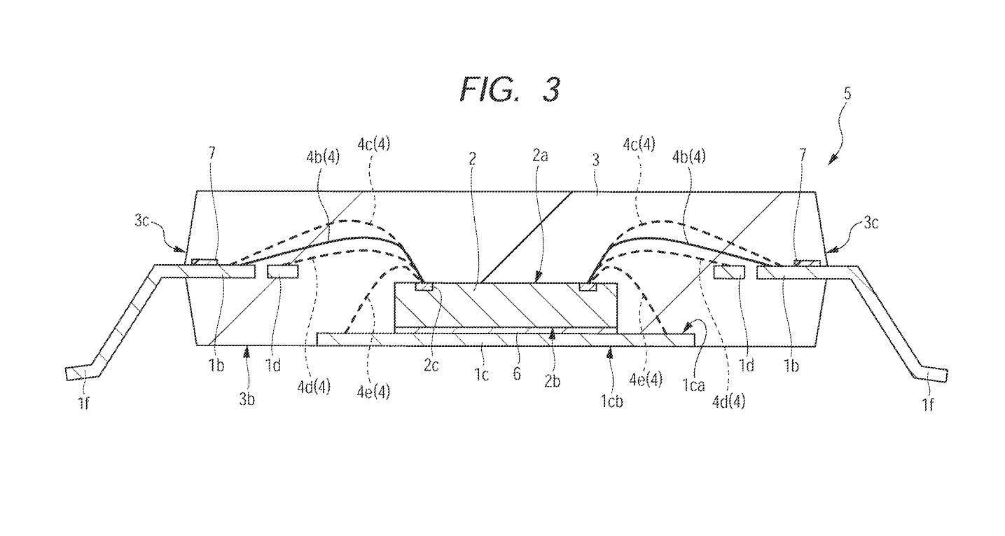

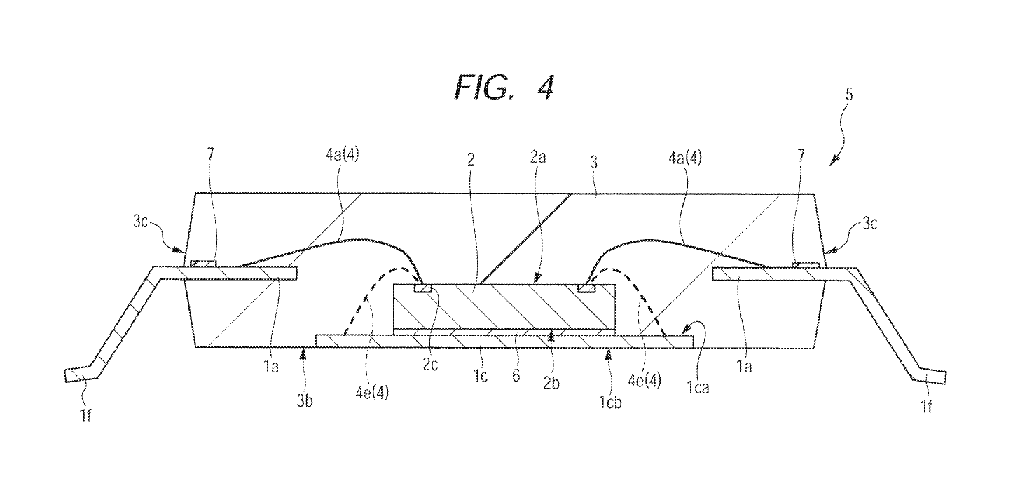

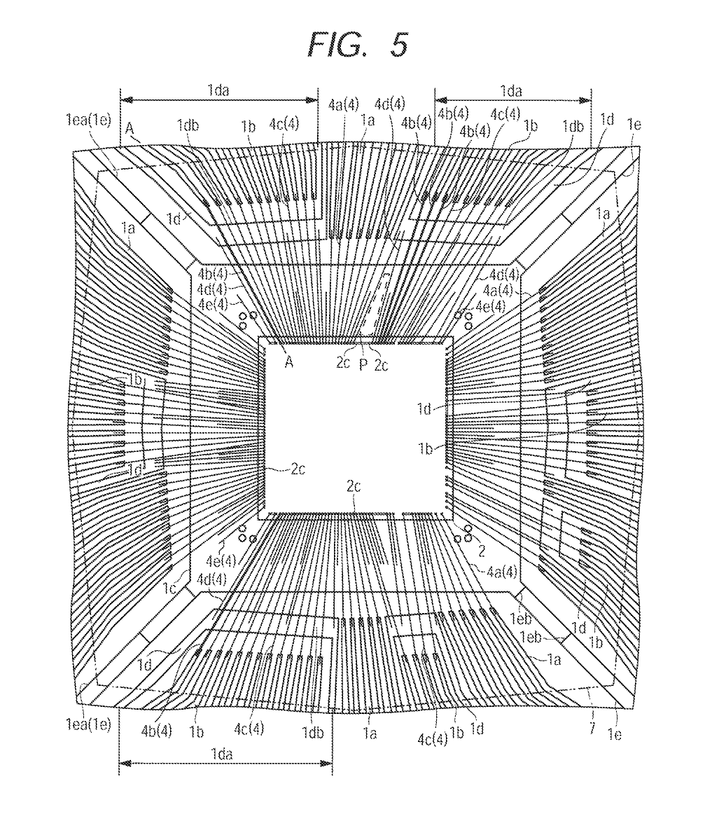

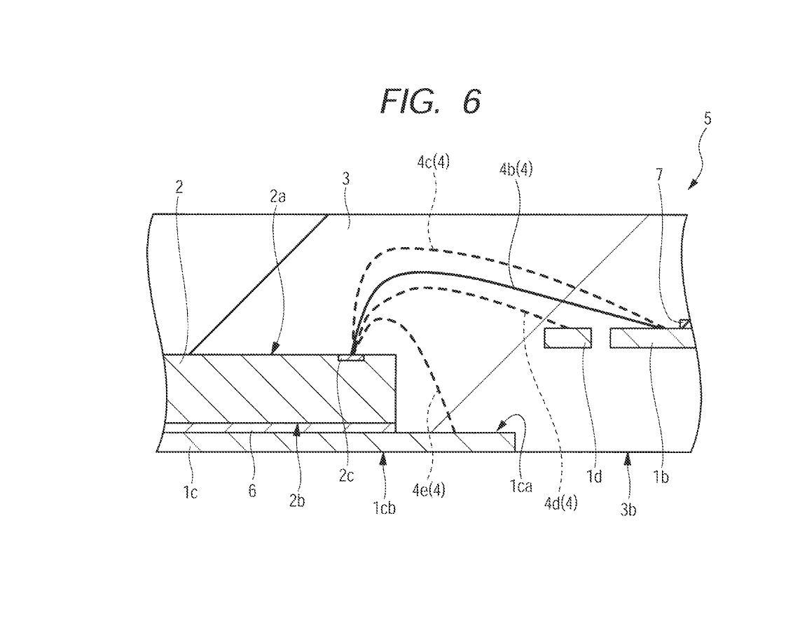

FIG. 1 is a plan view showing an example of the structure of the semiconductor device of the embodiment; FIG. 2 is a plan view showing the structure of the semiconductor device in FIG. 1 after passage of sealing body; FIG. 3 is a cross-sectional view showing the structure divided along lines A-A shown in FIG. 2; FIG. 4 is a cross-sectional view showing the structure divided along lines B-B shown in FIG. 2; FIG. 5 is a fragmentary enlarged plan view showing an example of the wiring status in the semiconductor structure shown in FIG. 1: FIG. 6 is a fragmentary enlarged cross-sectional view showing the structure divided along the lines A-A shown in FIG. 5.

The semiconductor device of the present embodiment shown in FIG. 1 is a resin-sealed type, and moreover is in a multi-pinning semiconductor package. Here, a description is given using as an example, a QFP (Quad Flat Package) 5 having plural outer leads (partial, electrode terminals, external coupling terminals) if respectively protruding outwards in four directions from the sealing body 3 formed from resin material and bend-formed in a gull wing shape.

Also as shown in FIG. 3, the QFP (semiconductor device) 5 contains a structure that boosts the heat radiating efficiency by way of a lower surface (rear side) 1cb of die pad 1c over which a semiconductor chip 2 is mounted, and that is exposed from the sealing body 3. In other words, the QFP5 is a high heat radiating type semiconductor package. More specifically, the QFP5 is a structure in which the lower surface 1cb of die pad 1c is exposed from the mounting surface 3b which is the rear side of the sealing body 3.

The structure of the QFP (semiconductor device) 5 shown in FIG. 1 through FIG. 6 is described next.

The QFP5 contains a die pad (island, support piece) 1c containing an upper surface (chip mounted side) 1ca and a lower surface 1cb on the side opposite this upper surface 1ca; and plural inner leads (first lead, electrode) 1a mounted at the periphery of the die pad 1c, and plural inner leads (second lead, electrodes) 1b mounted at the periphery of the die pad 1c and also shorter than the respective plural inner leads 1a. The QFP5 further contains the bus bars (common lead, common electrode, electrode) 1d mounted at the periphery of the die pad 1c, and also mounted between the die pad 1c and the plural inner leads 1b as seen from a plan view.

The die pad 1c (also called chip mounting section or tab) as shown in FIG. 2, is supported on the corners by suspension leads 1e. In other words, on the QFP5, the die pad 1c is supported by four suspension leads 1e. A bent section 1eb for exposing the die pad 1c from the mounting surface 3b of sealing body 3 is formed on each of the suspension leads 1e. The position along the height direction of the die pad 1c in this way becomes a low position (the tab lowering processing is performed), and the lower surface 1cb is exposed from the sealing body 3 as shown in FIG. 3.

The inner leads 1a, 1b or bus bars 1d are mounted internally in the sealing body 3; and the plural outer leads 1f formed into one piece with these inner leads 1a, 1b or bus bars 1d, respectively protrude from the four side surfaces 3c of sealing body 3 as external coupling terminals. These plural outer leads 1f are also bend-formed into a gull wing shape.

The QFP5 further contains a semiconductor chip 2 including a main surface 2a, plural electrode pads (electrodes) 2c formed over the main surface 2a, and a rear surface 2b on the side opposite the main surface 2a. This semiconductor chip 2 is mounted over the upper surface 1ca of the die pad 1c.

The QFP5 further includes plural wires (conductors) 4 to respectively electrically couple the plural electrode pads 2c of the semiconductor chip 2 and the plural inner leads 1a, 1b and the bus bars 1d, and a sealing body 3 to seal a portion of the die pad 1c, the bus bars 1d, the semiconductor chip 2, and the plural wires 4.

The semiconductor chip 2 is formed for example from silicon, plural semiconductor elements are formed over that main surface 2a, and the plural semiconductor elements comprise an integrated circuit on the side of the main surface 2a. As shown in FIG. 5, the planar shape of the semiconductor chip 2 is a rectangle, and the plural electrode pads 2c are mounted along the sides of the main surface 2a of the semiconductor chip 2.

In describing each member in further detail here, the die pad 1c as shown in FIG. 3 is a plate-shaped member, and includes an upper surface 1ca, and a lower surface 1cb on the side opposite the upper surface 1ca. A semiconductor chip 2 is bonded over the upper surface 1ca of this die pad 1c for example by way of a die bond material (laminating adhesive, die bond film, DAF (Die Attach Film)) 6 such as Ag paste which is a conductive adhesive material. The outer size (upper surface 1ca size) of the die pad 1c as shown in FIG. 3 and FIG. 4 is larger than the outer size (size of main surface 2a or rear surface 2b) of the semiconductor chip 2. The QFP5 of the present embodiment is in other words a large tab structure.

In this way, by employing a large tab structure utilizing a die pad 1c whose upper surface 1ca (or lower surface 1cb) has a wider surface area than the semiconductor chip 2, the heat radiating effect from the die pad 1c can be enhanced, and the heat radiating efficiency of the QFP5 can be improved.

The QFP5 further includes a bus bar 1d serving as the common (jointly utilized) lead. The bus bar 1d for example summarized the power supply wires 4 into one lead having plural couplings within the package for the purpose of reducing the number of external terminals (outer leads 1f), and in this way reduces the number of external terminals. Other purposes are for multi-pinning or miniaturization of semiconductor devices.

Collectively gathering the ground (GND) wires 4 by wire die bonding (ground bonding) over the die pad 1c serves to reduce the number of external terminal (outer leads 1f) the same as the bus bar 1d. In other words, the QFP5 is a large tab structure and so is a structure allowing coupling of the wires 4 to the die pad 1c.

On the QFP5 of the present embodiment the bus bar 1d as shown in FIG. 2 is a shape joined on one end to the outer lead 1f, and the other end is joined to another outer lead 1f. Further, as seen from a plan view, the position on the end of the die pad 1c side of the bus bar 1d is a position arrayed approximately with the plurality of inner lead 1a positions at the edge of the die pad 1c.

Each of the plural inner leads 1b as seen from a plan view is mounted within a region enclosed by the bus bars 1d. The respective length (length from the outer circumference position of sealing body 3 to the tip of the die pad 1c side.) of the plural inner leads 1b is therefore shorter than the respective length of the plural inner leads 1a.

In other words, in the QFP5 of the present embodiment as shown in FIG. 5, a lead section (electrode section) 1db where the wire 4 of bus bar 1d is coupled, is mounted as seen from a plan view, between the tip of the plural inner leads 1b and the end of the die pad 1c and so in this way each of the plural inner leads 1b is mounted in a region enclosed by the bus bars 1d. Moreover, the tips of each of the plural inner leads 1b is at a position deviated (lowered) towards the outer side (towards outer leads 1f) of the sealing body 3 compared to the position of each of the tips of the plural inner leads 1a.

However, in the bus bar region (common lead region, common electrode region) 1da enclosed by one bus bar 1d, the tips on the die pad 1c side of the plural inner leads 1b are at arrayed positions as seen from a plan view.

Also as shown in FIG. 3, the respective heights of the bus bars 1d and each of the plural inner leads 1b are at the same height. Namely, in the QFP5 of the present embodiment, there is no bend-forming of the bus bar 1d at the position within the sealing body so that each of the plural inner leads 1a, each of the plural inner leads 1b, and the plural bus bars 1d are mounted at the same height.

There is no bend-forming of the respective bus bars 1d at positions within the sealing body so that there is no need to secure a space to mount a metal mold for forming a bend in the bus bar 1d in the bus bar region 1da shown in FIG. 5. Therefore, the tip on the die pad 1c side of the inner lead 1b on the end near the bus bar 1d can be mounted at a position arrayed as seen from a plan view, with the tip of the other inner leads 1b, in the above described bus bar region 1da.

The wire 4 of the QFP5 is described next. On the QFP5 as shown in FIG. 2 and FIG. 4, among the plural wires 4, the plural electrode pads 2c of the semiconductor chip 2 and the plural inner leads (first lead, electrode) 1a are electrically coupled by plural first wires (first conductor) 4a.

The plural electrode pads 2c of the semiconductor chip 2 and the plural inner leads (second lead, electrode) 1b are electrically coupled to any of the second wire (second conductor) 4b or the third wire (third conductor) 4c. As shown in FIG. 3, each of the plural second wires 4b and the plural third wires 4c are formed so as to pass over the bus bars 1d. The respective loop heights of the plural second wires 4b are formed at this time so as to be lower than the respective loop height of the plural third wires 4c.

In other words, there are two types of wire 4 loop heights which are the second wire 4b and the third wire 4c in the bus bar region 1da where the second wire 4b and the third wire 4c are formed.

Both of the second wire 4b and third wire 4c are not necessarily mounted in these bus bar regions 1da in all of the bus bars 1d in the QFP5 of the present embodiment, just the plural third wires 4c within bus bar region 1da may be respectively coupled to each of the plural inner leads 1b. In this case, there is only one type of loop height for wire 4 (third wire 4c) within the bus bar region 1da.

Whereupon, points where preferable to install two types of wire 4 loop heights in the bus bar region 1da of an optional bus bar 1d for the QFP5 of the present embodiment are described.

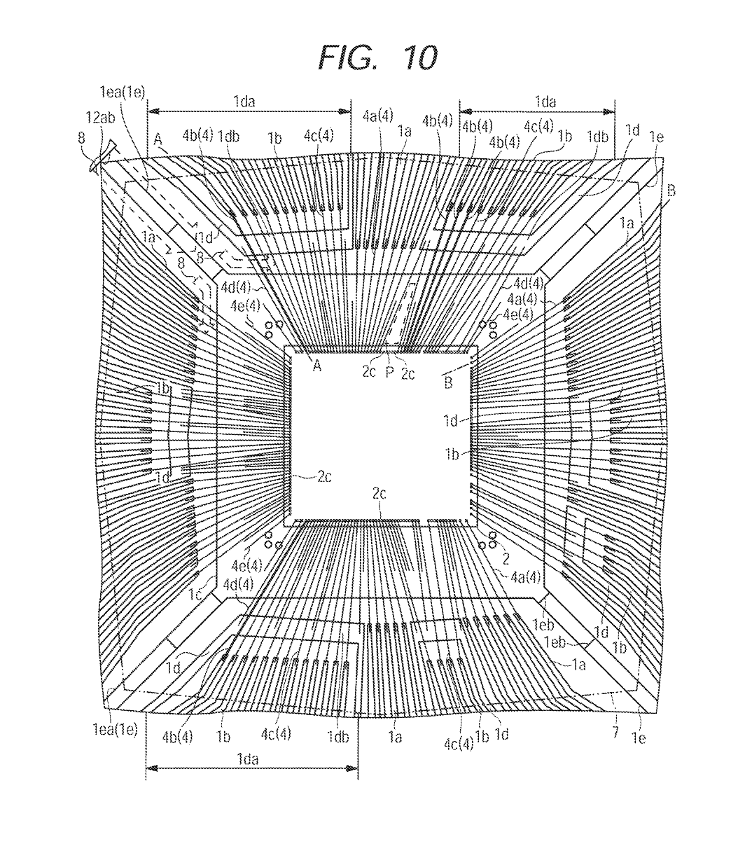

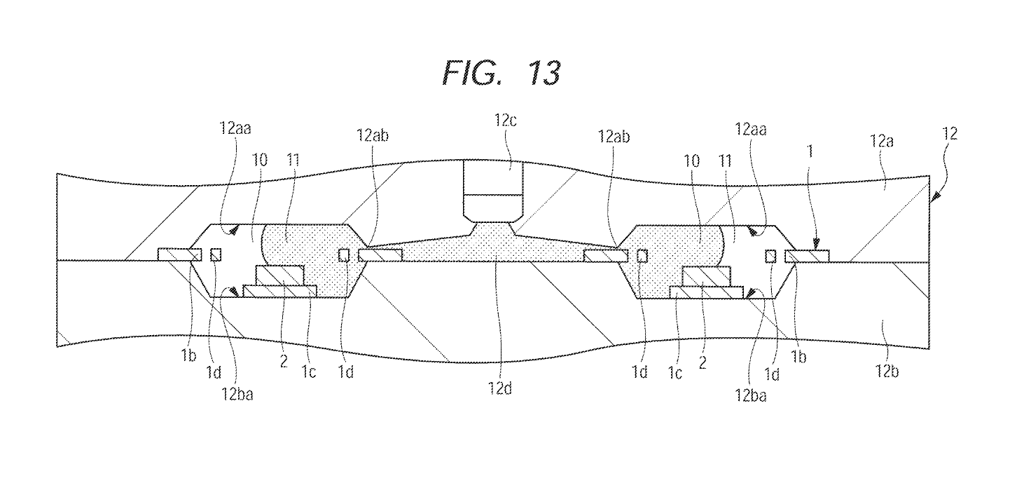

Among the four suspension leads 1e supporting the die pad 1c in the QFP5, there is a standard suspension lead 1ea corresponding to the position of the gate 12ab shown in FIG. 10 that supplies the sealing resin (resin, see FIG. 13) during the resin sealing when assembling the QFP5.

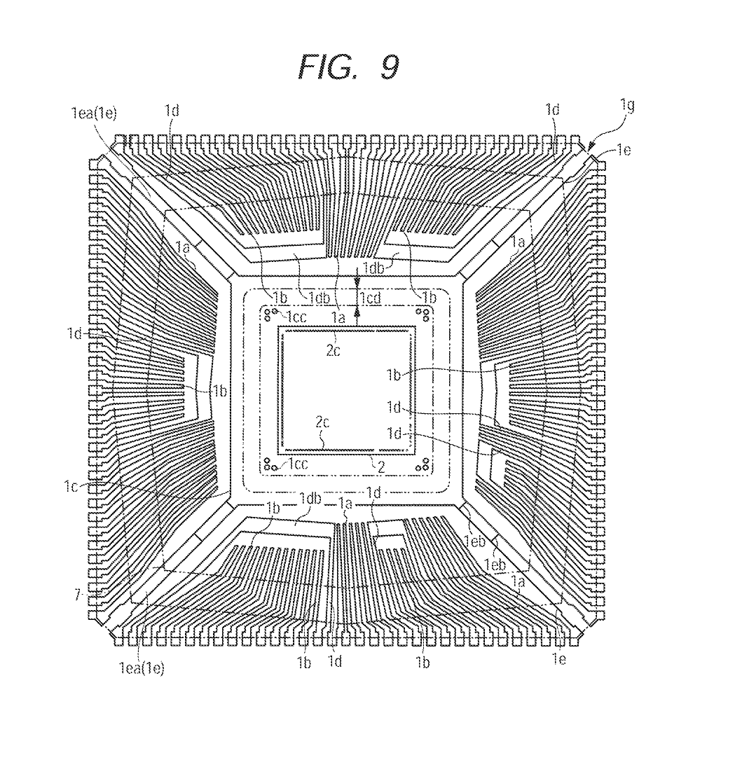

Therefore during the resin sealing, the loop height of the wire 4 must be set while taking the wire sweep relative to the flow direction (see FIG. 9) 8 of the sealing resin 10 flowing from the vicinity of the standard suspension lead 1ea.

First of all, wire sweep tends to easily occur due to the resin pressure from the sealing resin 10 flowing in the vicinity of the standard suspension lead 1ea so that when there is a bus bar region 1da near the bus bars 1d in the vicinity of the standard suspension lead 1ea, a second wire 4b and a third wire 4c are preferably formed passing over the bus bars 1d relative to this bus bar region 1da, and formed at different loop heights.

Also as shown in the spatial section P in FIG. 5, among the wire arrays comparatively close to the standard suspension lead 1ea, a spatial section P having no wires 4 in the wire array is formed when there are plural collectively mounted electrode pads 2c not coupled to the wires 4 among the electrode pads 2c of the semiconductor chip 2.

In this type of spatial section P, when the sealing resin 10 has flowed in during the resin sealing, there are no wires 4 so that the resistance to the sealing resin 10 is small and the sealing resin 10 flow speed increases. Consequently, when a wire 4 having a high loop is formed immediately after the downstream side in the flow direction 8 of sealing resin 10 in this spatial section P, the resistance to the sealing resin 10 increases and wire sweep tends to easily occur.

Therefore when there is a bus bar region 1da by the bus bars 1d in the vicinity (immediately after) after flow to the downstream side of spatial section P, a second wire 4b and a third wire 4c are preferably formed passing over the bus bar 1d relative to this bus bar region 1da, and also formed at different loop heights.

In the bus bar region 1da where the second wire 4b and a third wire 4c are formed, the second wire 4b is mounted nearer to the standard suspension lead 1ea than the third wire 4c. In other words, compared to the third wire 4c having a high loop height, a second wire 4b having a low loop height is mounted more to the side near the standard suspension lead 1ea, in the bus bar region 1da where the second wire 4b and a third wire 4c are formed.

Whereupon, in the QFP5 of the present embodiment, among the plural inner leads 1b mounted within this bus bar region 1da, a second wire 4b is electrically coupled to the inner lead 1b mounted at the end near the standard suspension lead lea, in the bus bar region 1da where the second wire 4b and a third wire 4c are formed.

Namely, in the bus bar region 1da where the second wire 4b and a third wire 4c are formed, the second wire 4b with a low loop height is mounted at the end near the standard suspension lead 1ea in FIG. 5, and therefore in the bus bar region 1da, plural wires 4 are mounted so that the loop height become gradually higher from the standard suspension lead 1ea.

Plural second wires 4b having a low loop height may be consecutively mounted from the edge near the standard suspension lead 1ea, in the bus bar region 1da.

In the bus bar region 1da, on the standard suspension lead 1ea side of the second wire 4b, a fourth wire (fourth conductor) 4d having a loop height lower than the second wire 4b is mounted in the vicinity of the second wire 4b as shown in FIG. 6; and this fourth wire 4d is electrically coupled to the bus bar 1d as shown in FIG. 5.

Further, on the standard suspension lead 1ea side of the fourth wire 4d in the bus bar region 1da, there are plural consecutive electrode pads 2c of semiconductor chip 2 not coupled to any wire 4. Restated in other words, forming plural consecutive electrode pads 2c not coupled to any wire 4, serves to form a spatial section P as shown in FIG. 5, and also a fourth wire 4d coupled to the bus bar 1d is mounted on the downstream side (side away from the standard suspension lead 1ea) of the spatial section P. Also, on the downstream side of this fourth wire 4d, three second wires 4b having a loop height higher than the fourth wire 4d, pass over the respective bus bars 1d and couple to the inner lead 1b. Then, on the downstream side of these three second wires 4b, a third wire 4c having a loop height higher than the second wire 4b, passes over the bus bars 1d, and couples to other inner leads 1b.

In other words, each wire 4 is formed so that the loop height of the wire 4 gradually becomes higher at points where there is a spatial section P, immediately after the downstream side of spatial section P (side away from the standard suspension lead 1ea).

In the QFP5 as shown in FIG. 6, a fifth wire (fifth conductor) 4e having a loop height lower than the fourth wire 4d is electrically coupled to the die pad 1c. The fifth wire 4e is a so-called ground bonded wire. In other words, in the QFP5, the die pad 1c is at GND (ground) voltage potential. The bus bar 1d and the plural fourth wires 4d joined to the bus bar 1d are for example at the power supply voltage potential.

In the QFP5, among the loop heights of each wire 4, the fifth wire 4e is the lowest, and is a state in which the fifth wire 4e<the fourth wire 4d=the first wire 4a<the second wire 4b<the third wire 4c.

In the QFP5 of the present embodiment, as shown in FIG. 2, a ring-shaped tape material 7 is attached to the region on the outer side of the coupling points for each wire 4, over the surface of each inner lead 1a, 1b and each bus bar 1d.

This tape material 7 prevents flapping in the assembly process for the plural inner leads 1a, 1b or bus bar 1d, and the attaching of the tape material 7 reduces deformation (warping) of the inner leads 1a, 1b and bus bar 1d in the assembly process.

The plural wires 4 (first wire 4a, second wire 4b, third wire 4c, fourth wire 4d, and fifth wire 4e) are for example narrow wires with a diameter of approximately 18 to 20 μm. The material utilized as the main constituent is preferably copper but the material utilized as the main constituent is not limited to copper.

Also, the die pad 1c, inner leads 1a, 1b, outer lead 1f, bus bar 1d, and the suspension lead 1e are comprised of an alloy whose main constituent is copper but are not limited to this material.

The sealing body 3 is made for example from an epoxy type thermosetting resin.

In the QFP5 of the present embodiment, the bus bar 1d is not subjected to bend forming and therefore the bus bar 1d and inner leads 1a, 1b are the same height. In other words, there is no bend forming at the position within the sealing body relative to the respective bus bars 1d so that there is no need to secure space in the bus bar region 1da for mounting a metal mold for forming a bend in the bus bar 1d.

In the bus bar region 1da, the tip on the die pad 1c side of the inner lead 1b mounted on the end near the bus bar 1d among the array of inner leads 1b, can in this way be mounted at a position aligned, as seen from a plan view with the tips of other inner leads 1b, with no deviations (offsets) in the outer circumferential direction of the sealing body 3.

In other words, the length of the inner lead 1b at the end mounted near the bus bar 1d, can be made the same length as the other inner leads 1b, without requiring shortening.

Consequently, the inner lead 1b mounted on the end in the bus bar region 1da is not shortened so the length of the wire (second wire 4b) coupled to this inner lead 1b can be made shorter.

The wire sweep occurring in the resin sealing process of this wire 4 can in this way be reduced.

Also, the length of the wire 4 (second wire 4b) coupled to the inner lead 1b mounted at the end in the bus bar region 1da is short, so that the wiring cost of the wire 4 can be reduced, and the cost of the QFP5 can be lowered.

Further, no metal mold is needed for bend forming on the bus bar 1d so that the manufacturing cost of the QFP5 can be lowered.

The plural wires 4 (first wire 4a, second wire 4b, third wire 4c, fourth wire 4d, and fifth wire 4e) are comprised of a material whose main constituent is copper (copper wire) and the copper (Cu) wire is hard compared to gold (Au) wire so that the strength of the wire 4 can be enhanced and wire sweep in the resin sealing process can be limited.

Copper wire is also lower in cost compared to gold wire so that a low cost QFP5 can be achieved.

The assembly process for the semiconductor device (QFP5) of the present embodiment is described next.

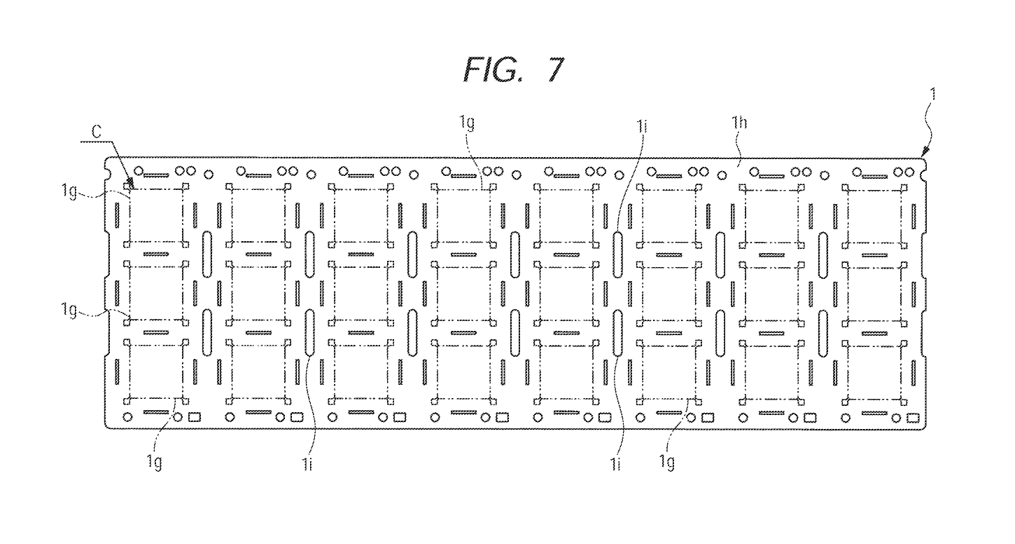

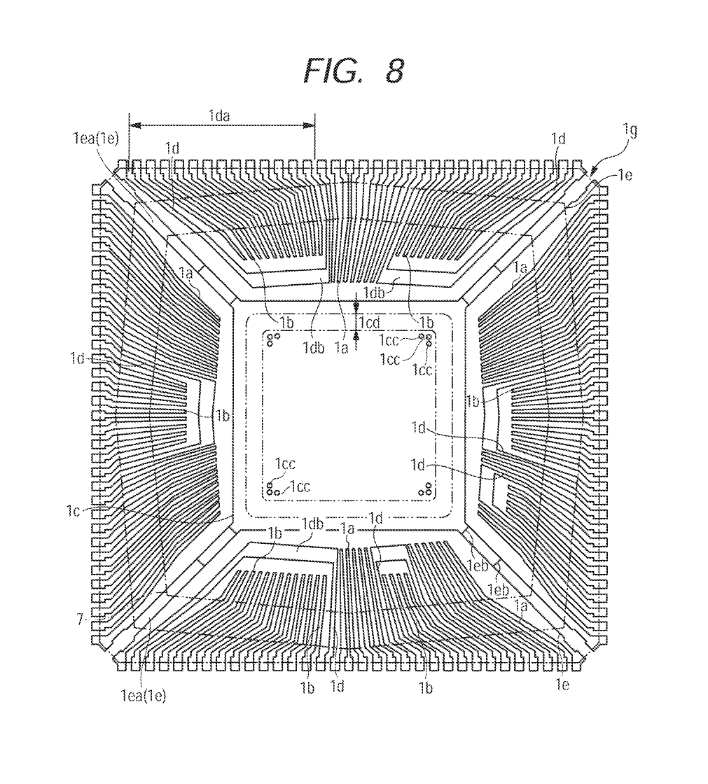

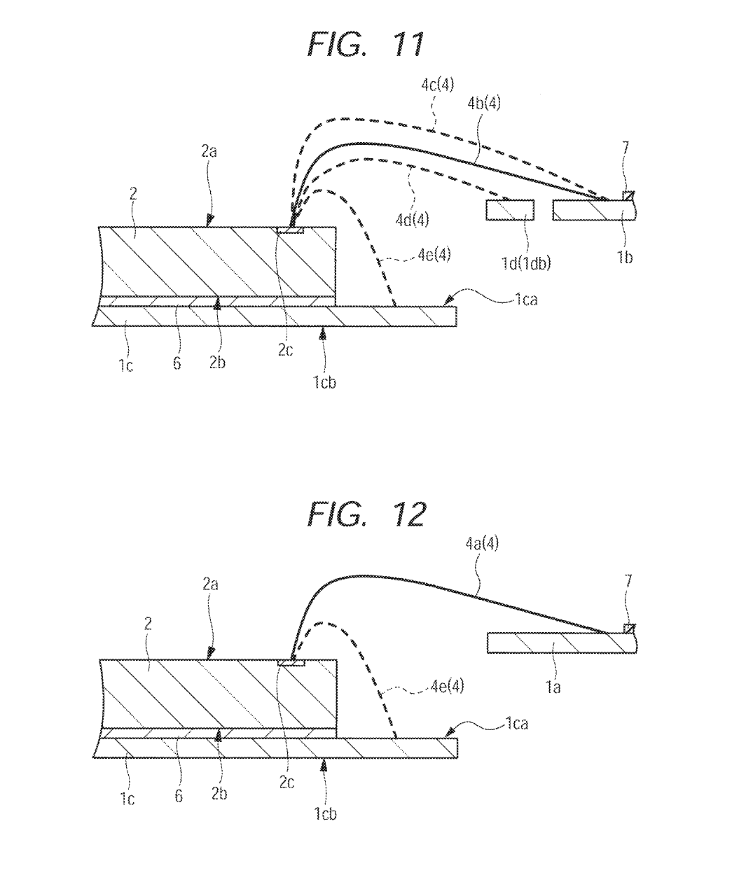

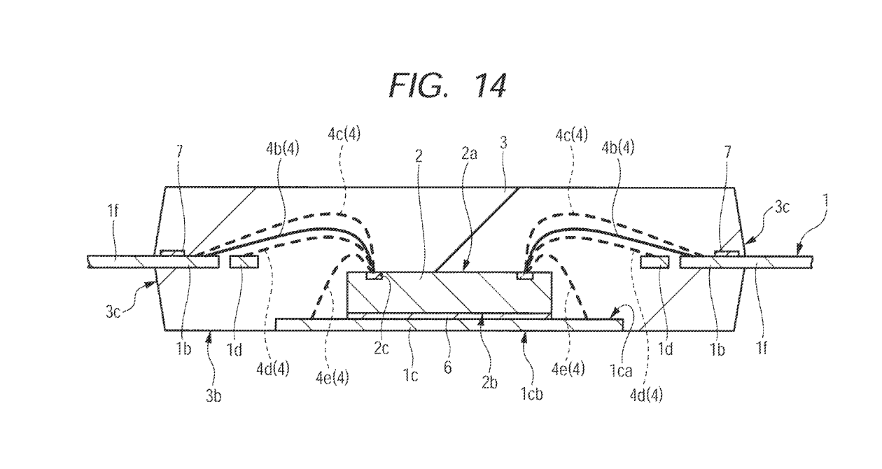

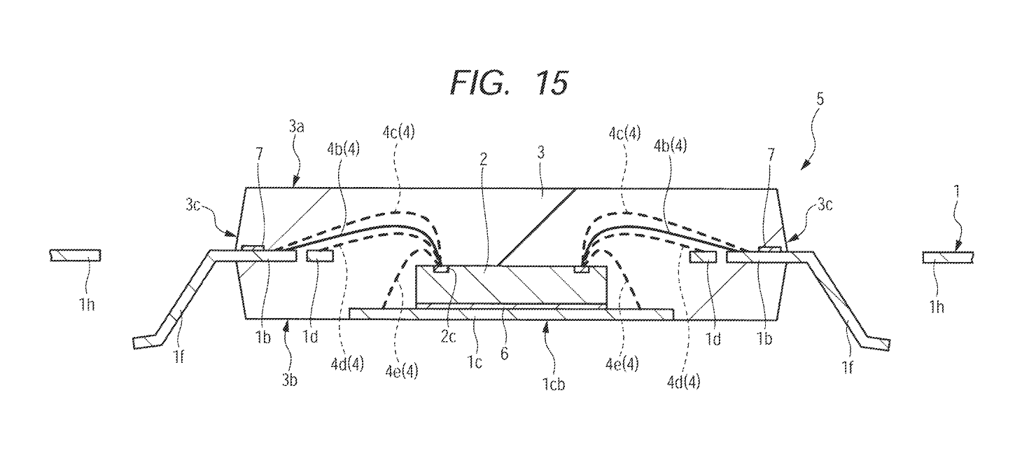

FIG. 7 is a fragmentary plan view showing an example of the structure of the lead frame utilized in assembly of the semiconductor device shown in FIG. 1. FIG. 8 is a fragmentary enlarged plan view showing an enlargement of the C section shown in FIG. 7. FIG. 9 is a fragmentary plan view showing an example of the structure after die bonding during the assembly of the semiconductor device shown in FIG. 1. FIG. 10 is a fragmentary plan view showing an example of the structure after die bonding during assembly of the semiconductor device shown in FIG. 1. FIG. 11 is a fragmentary cross-sectional view showing the structure divided along the lines A-A shown in FIG. 10. FIG. 12 is a fragmentary cross-sectional view showing the structure divided along the lines B-B shown in FIG. 10. Further, FIG. 13 is a fragmentary cross-sectional view showing an example of the structure during resin molding in the assembly of the semiconductor device shown in FIG. 1. FIG. 14 is a fragmentary cross-sectional view showing an example of the structure after resin molding in the assembly of the semiconductor device shown in FIG. 1. FIG. 15 is a fragmentary cross-sectional view showing an example of the structure during cutting and molding in the assembly of the semiconductor device shown in FIG. 1.

A lead frame 1 is first of all prepared in FIG. 7. The lead frame 1 is a multiple string plate material in a matrix formed from plural device regions 1g. Each of the device regions 1g is enclosed by a frame 1h. The slit holes 1i are formed between the adjacent device regions 1g. When stress is applied to the lead frame 1 during assembly, the slit holes 1i serve as a shape that alleviates the stress.

The lead frame 1 is for example comprised of an alloy material whose main constituent is copper but the lead frame is not limited to this material.

In each device region 1g shown in FIG. 8, a die pad (island, support piece) 1c containing an upper surface (chip mounting surface) 1ca and a lower surface (rear surface) 1cb on that opposite side in FIG. 3, four suspension leads 1e supporting the die pad 1c, plural inner leads (first lead, electrode) 1a mounted at the periphery of the die pad 1c, and plural inner leads (second lead, electrode) 1b whose lengths are respectively shorter than the plural inner leads 1a.

Further, plural bus bars (common lead, common electrode, electrode) 1db containing lead sections (electrode sections) mounted over the region between the die pad 1c and the plural inner leads 1b as seen from a plan view.

The outer leads if are formed to each inner lead 1a, 1b and each bus bar 1d in one piece as shown in FIG. 2.

The surface of the respective inner lead 1a, 1b tips and the surface of the lead sections 1db of the bus bar 1d are coated with silver (Ag) coating to provide a satisfactory coupling with the wire (conductor) 4.

A bent section 1eb is formed in each suspension lead 1e, and the die pad 1c is mounted at a position lower than the inner lead 1a, 1b and the bus bar 1d. In other words, a tab lowering process is performed on the lead frame 1.

A dimple section 1cc serving as a position landmark is formed over the upper surface of each die pad 1c when mounting the semiconductor chip 2 in the die bonding process. The semiconductor chip 2 is mounted over the die pad 1c so as not to hide this dimple section 1cc.

A plate-coated section 1cd is formed on the outer side of the dimple section 1cc. Ground die bonding is implemented on this plate-coated section 1cd. A silver (Ag) plating for example is therefore coated on the plate-coated section 1cd.

Plural inner leads 1a and inner leads 1b, and bus bars 1d are respectively formed among the adjacent suspension leads 1e. The plural inner leads 1b are mounted within the bus bar region (common lead resin, common electrode region) 1da which is a region enclosed by the bus bars 1d. Each length of the plural inner leads 1b is therefore shorter than each of the plural inner leads 1a.

The respective tip positions of the plural inner leads 1a are the same positions as the lead section 1db where the wires of the bus bar region 1da are coupled, and the tips are arrayed as seen from a plan view.

There is no bend forming at the position on the bus bar 1d so there is no need to secure a space in the bus bar region 1da for mounting a metal mold to form a bend in the bus bar 1d.

Therefore, in the bus bar region 1da, the tip on the die pad 1c side of the inner lead 1b mounted on the end near the bus bar 1d among the array of inner leads 1b, can in this way be consequently mounted at a position arrayed as seen from a plan view with the tips of other inner leads 1b, with no deviations (offsets) in the outer circumferential direction of the device region 1g. The tips of the plural inner leads 1b within the bus bar region 1da are in other words all mounted at an arrayed position as seen from a plan view.

In the lead frame 1 of the present embodiment, there is no bend forming on the bus bar 1d, and therefore the plural inner leads 1a, plural inner leads 1b, and plural bus bars 1d are mounted at the same height.

Also, a ring-shaped tape material 7 is attached to the surface of the plural inner leads 1a, 1b and bus bar 1d, over each device region 1g. The tape material 7 in this way prevents flapping in the assembly process for the plural inner leads 1a, 1b or bus bar 1d, and also reduces deformation (warping) of the inner leads 1a, 1b or bus bar 1d that occurs due to flapping in the assembly process.

Die bonding is next performed as shown in FIG. 9. Here, as shown in FIG. 3, a semiconductor chip 2 including a main surface 2a, plural electrode pads (electrodes) 2c formed over the periphery of the main surface 2a, and a rear surface 2b on the side opposite the main surface 2a are mounted over the upper surface 1ca of the die pad 1c.

A die bond material (adhesive material, laminating adhesive, die bond film, DAF) 6 such as Ag paste shown in FIG. 3 is coated at this time over the upper surface 1ca of the die pad 1c. After coating, the semiconductor chip 2 picked up and conveyed for example by a collet not shown in the drawings is mounted over the upper surface 1ca of the die pad 1c, and as shown in FIG. 9, is attached by way of the die bond material 6 over the upper surface 1ca of the die pad 1c in a state where the main surface 2a of the semiconductor chip 2 is facing upwards.

Afterwards, the wire bonding as shown in FIG. 10 is performed. In this wire bonding process, each of the plural electrode pads 2c of the semiconductor chip 2, die pads 1c, bus bars 1d, the plural inner leads (first lead, electrode) 1a, and the plural inner leads (second lead, electrode) 1b are electrically coupled by way of the plural wires 4.

In this wire bonding process, the wire bonding is performed in the order of low loop height from among the plural types of loop heights of the wires 4.

In the QFP5 of the present embodiment, the ground bonding which is the wire bonding to the die pad 1c has the lowest loop height so first of all as shown in FIG. 11 and FIG. 12, the plural fifth wires (fifth conductors) 4e are electrically coupled (ground bonding is performed) to the die pad 1c. In this case, the fifth wire 4e is coupled to the plate-coated section 1cd of the upper surface 1ca of the die pad 1c shown in FIG. 8.

Afterwards, wire bonding to the inner lead 1a and the bus bar 1d serving as the common lead is performed. In other words, each of the plural inner leads 1a and the plural bus bars 1d are the same height, and the positions of each tip of the plural inner leads 1a, and the positions of the respective plural lead sections 1db of the bus bar 1d are approximately arrayed as seen from a plan view so that the wire bonding to the inner leads 1a and bus bars 1d is performed in the same process.

The plural electrode pads 2c of the semiconductor chip 2 and each of the plural inner leads 1a are electrically coupled by plural first wires (first conductors) 4a as shown in FIG. 12. At this time, wire bonding is performed by setting the loop height of the plural first wires 4a higher than the respective loop heights of the plural fifth wires 4e.

Further, the plural electrode pads 2c of semiconductor chip 2, and the lead sections 1db of the plural bus bars 1d are electrically coupled by the plural fourth wires (fourth conductor) 4d as shown in FIG. 11. At this time, wire bonding is performed by setting the loop height of the plural fourth wires 4d to the same respective loop heights as the plural first wires 4a.

Among the four suspension leads 1e supporting the die pad 1c in the lead frame 1, there is a standard suspension lead 1ea corresponding to the position of the gate 12ab in FIG. 10 for supplying the sealing body (resin, see FIG. 13) in the resin sealing process.

In the lead frame 1, when a region enclosed by one bus bar 1d is set as the bus bar region (common lead region, common electrode region) 1da, a fourth wire 4d is consequently formed so as to be adjacent to the second wire (second conductor) 4b and so that the loop height of a fourth wire 4 is lower than the second wire 4b in this bus bar region 1da. In this case, a fourth wire 4d is coupled to the bus bar 1d so that the fourth wire 4d is mounted nearer the standard suspensions lead 1ea than the second wire 4b.

However, at this stage there has still been no wire bonding of the second wire 4b so that at least any among the plural fourth wires 4d for wire bonding are coupled to the end on the standard suspension lead 1ea side of the lead section 1db of each bus bar 1d, and also at the same loop height as the first wire 4a.

Also among the plural electrode pads 2c of semiconductor chip 2 as shown in the spatial section P in FIG. 10, in locations where there are consecutive plural electrode pads 2c not coupled to any of the wires 4; in the bus bar region 1da, these plural electrode pads 2c not coupled to these wires 4, couple the fourth wires 4d to the bus bar 1d so as to mount on at least the standard suspension lead 1ea side of fourth wire 4d.

In the bus bar 1d in the vicinity of the standard suspension lead 1ea, a fourth wire 4d is coupled to the end of the standard suspension lead 1ea side of lead section 1db of this bus bar 1d at the same loop height as the first wire 4a, even in the vicinity of corners of die pad 1c where the standard suspension lead 1ea is coupled.

The plural electrode pads 2c of semiconductor chip 2 are afterwards electrically coupled by way of the plural second wire 4b to any of the plural inner leads 1b mounted in the bus bar region 1da. In that case, each of the plural second wires 4b are formed to pass over the bus bar 1d. Moreover, the second wire 4b is wire bonded so that the loop height as shown in FIG. 11 is higher than the respective loop heights of the fifth wire 4e, the first wire 4a, and the fourth wire 4d.

Further, as shown in FIG. 10, the second wire 4b in the bus bar region 1da is electrically coupled to the inner lead 1b at the end-most position from the standard suspension lead 1ea side.

The fourth wire 4d having a loop height lower than the second wire 4b on the standard suspension lead 1ea side of the second wire 4b in the bus bar region 1da, can in this way be coupled to the bus bar 1d in a state where mounted in proximity to the second wire 4b.

Restated in other words, a fourth wire 4d is coupled to the bus bar 1d in the bus bar region 1da, in a state where adjacent to the second wire 4b, at a loop height lower than the second wire 4b, and nearer the standard suspension lead lea than the second wire 4b.

Also, those plural electrode pads 2c of semiconductor chip 2 not coupled to any of the wires 4 are consecutively mounted on the standard suspension lead 1ea side of the fourth wire 4d in the bus bar region 1da, and thus a spatial section P is present within the wire array formed as described here.

The second wire 4b need not be used in every bus bar region 1da, the bus bar region 1da for wire bonding the second wire 4b is a bus bar region 1da including locations where consecutive plural electrode pad 2c that no wires 4 are coupled among the plural electrode pads 2c shown in the spatial section P in FIG. 10, or a bus bar region 1da in the vicinity of the standard suspension lead 1ea.

The second wire 4b may be wire bonded to each of the consecutively arrayed inner leads 1b from the inner lead 1b mounted at the end among the inner lead 1b array.

Afterwards, the plural electrode pads 2c of semiconductor chip 2 and any of the other leads of inner lead 1b may be formed to pass over the bus bar 1d by way of the third wire (third conductor) 4c and also electrically couple to the inner lead 1b at a higher loop height than the second wire 4b.

In the respective plural bus bar regions 1da in other words, the remaining plural inner leads (other leads) 1b not coupled to the second wire 4b are coupled to the corresponding plural electrode pads 2c of semiconductor chip 2 by way of the plural third wires 4c. In that case, the third wires 4c pass over the bus bar 1d, and also electrically couple to the plural inner leads (other leads) 1b at a loop height higher than the second wire 4b.

Further, in the plural bus bar regions 1da where the second wire 4b is coupled, a third wire 4c is formed so that the second wire 4b is positioned nearer the standard suspension lead 1ea than the third wire 4c.

Each of the wires 4 in this way attains a state where respectively electrically coupled to the plural electrode pads 2c of semiconductor chip 2, and the plural inner leads 1a, 1b and bus bars 1d corresponding to the plural electrode pads 2c of semiconductor chip 2.

The wire bonding of the present embodiment in other words, includes wire bonding implemented so that the loop height of the wire 4 passing over the bus bar 1d is two types of loop height for second wire 4b and third wire 4c; and includes the bus bar region 1da where the second wire 4b and third wire 4c using these two types of loop height are formed.

Then, in the bus bar region 1da where the second wire 4b and third wire 4c are formed, each wire 4 is mounted so that the wire 4 loop height becomes gradually higher from the standard suspension lead 1ea side, since the second wire 4b is mounted at a loop height lower than at the end from the standard suspension lead 1ea.

The standard suspension lead 1ea may be set so that another adjoining suspension lead 1e (any among the two suspension leads 1e positioned on the plunger 12c side shown in FIG. 13) is utilized as the standard suspension lead 1ea.

Therefore, whichever suspension lead 1e is set for the standard suspension lead 1ea, a second wire 4b and third wire 4c may be formed at two types of loop heights as described above, even in a bus bar region 1da in the vicinity of any of the standard suspension lead 1ea, so that a countermeasure to wire sweep is implemented.

Each wire 4 is preferably a material whose main constituent is for example copper. Copper wire is stiffer compared to gold (Au) wire so that utilizing copper (Cu) wire boosts the strength of the wire 4 and limits the wire sweep in the resin sealing process.

Copper wire is also lower in cost compared to gold wire so that the cost of QFP5 assembly can be reduced.

The resin molding (resin sealing) is performed as shown in FIG. 13 after the wire bonding. Here, the sealing resin 10 seals the inner leads 1a, 1b, the bus bar 1d, the semiconductor chip 2, and the plural wires 4 so that the outer lead (a section, electrode terminal, external electrode terminal) 1f in FIG. 14 which is joined as one piece respectively to the plural inner leads 1a, 1b and bus bar 1d shown in FIG. 10 protrudes from the sealing body 3.

In this resin molding as shown in FIG. 13, a resin forming mold (metal mold) 12 including an upper mold 12a and lower mold 12b pair is first of all prepared, a lead frame 1 is mounted in the space section 11 formed by the respective metal mold cavities 12ba, 12ba, and the upper mold 12a and lower mold 12b are then clamped.

The heated sealing resin 10 is then pressed out by the plunger 12c, and the sealing resin 10 is supplied by way of the runner 12d and gate 12ab to the space section 11 formed by the cavities 12ba, 12ba.

The sealing resin 10 of FIG. 13 is in this way poured from the gate 12ab shown in FIG. 10 to each device region 1g of the lead frame 1. The sealing resin 10 flows into each device region 1g along the flow direction 8.

A second wire 4b having a low loop height is mounted at the end near the standard suspension lead 1ea; in the bus bar region 1da near the standard suspension lead 1ea corresponding to the position of gate 12ab, and in the bus bar region 1da near the spatial section P where electrode pad 2c not coupled to the wire 4 are collectively mounted. Each wire layer 4 is mounted so that the wire loop height of the wire 4 becomes gradually higher from the standard suspension lead 1ea side.

In other words, in the above described bus bar region 1da, the loop height of the wire 4 becomes gradually higher relative to the flow direction 8 of the above described sealing resin 10, so that the resistance to the wire 4 due to the flow of resin is alleviated and consequently the occurrence of wire sweep can be reduced.

The pressure (load) sustained from the flow of the sealing resin 10 as seen from the wire side, starts out small and is alleviated to gradually become larger, so that the occurrence of wire sweep during the resin molding can be reduced.

Consequently, the occurrence of electrical wiring shorts due to wire sweep can be prevented, and the reliability improved in the QFP5 assembly process.

Performing wire bonding that passes over the bus bar, allows forming the wire 4 at a high loop height so that for the second wire 4b and third wire 4c where wire sweep tends to easily occur, changing the loop heights by setting different loop heights allows limiting the occurrence of electrical wiring shorts, even for example in cases where wire sweep has occurred.

By next ending the supply of sealing resin 10 to the space section 11 of the cavities 12aa, 12ba and performing bake processing and so on, the sealing body 3 shown in FIG. 14 is formed, and the resin molding is now finished. The lower surface 1cb of the die pad 1c is exposed from the mounting surface 3b of the sealing body 3.

The surface 3a of the sealing body 3 is then subjected to the desired marking after completion of the resin mold.

Cutting and molding is then performed. The respective plural outer leads 1f exposed from the sealing body 3 are each cut off from the lead frame 1 as shown in FIG. 15. After being cut off, each of the plural outer leads if are bend-formed into a gull wing shape.

The above processing completes the assembly of the QFP5.

The invention rendered by the inventors was specifically described above in detail based on the embodiment of the invention. However the present invention is not limited by the embodiment and all manner of changes and adaptations not departing from the spirit and scope of the invention are permissible.

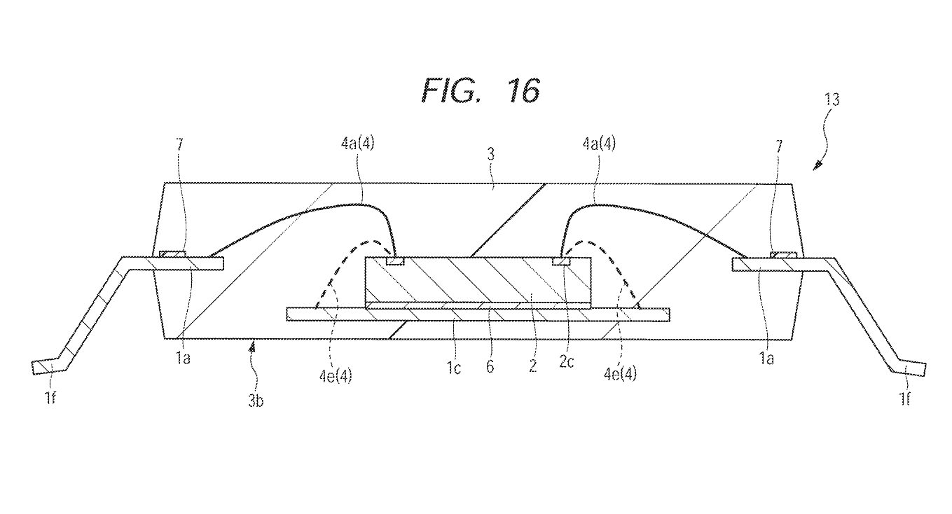

For example, in the embodiment, the semiconductor device (QFP5) was described in view of the need for a heat radiating effect for the case where utilizing a tab exposure type structure to expose the lower surface 1cb of the die pad 1c from the mounting surface 3b of the sealing body 3. However, the semiconductor device may utilize a tab embedded type shown in the modification in FIG. 16.

The semiconductor device shown in FIG. 16 is in other words, a semiconductor device that is a modification of the embodiment, and is a tab embedded type QFP (Quad Flat Package) 13 where the die pad 1c is embedded into the sealing body 3.

The tab embedded type QFP 13 of the modification is also capable of rendering the same effect as the QFP5 of the above embodiment.

What is claimed is:

1. A manufacturing method for a semiconductor device comprising the steps of:
(a) preparing a lead frame including a die pad that contains a chip mounting surface, a plurality of suspension leads that support the die pad, a plurality of first leads that are mounted at the periphery of the die pad, a plurality of second leads whose lengths are shorter than the respective first leads, and a common lead that is mounted between the die pad and the second leads as seen from a plan view;
(b) mounting a semiconductor chip formed with a plurality of electrode pads over the main surface over the chip mounting surface of the die pad;
(c) coupling electrically by way of a plurality of wires, each of the electrode pads of the semiconductor chip, the common lead, and the first leads and the second leads;
(d) sealing the common lead, the semiconductor chip, and the wires with resin so that a portion of each of the first and second leads and the common lead are exposed from the sealing body; and
(e) cutting a plurality of outer leads that are exposed from the sealing body from the lead frame;
wherein, in the step (c):
a first wire among the wires electrically couples the electrode pad and the first lead,
a second wire among the wires passes over the common lead and electrically couples the electrode pad and any lead of the second leads,
a third wire among the wires passes over the common lead and also electrically couples the electrode pad and any of the another second leads at a loop height higher than the second wire, and
the second wire is mounted closer than the third wire in the common lead region corresponding to the common lead, relative to the standard suspension lead at the position matching the gate for supplying resin during the resin sealing among the suspension leads.

2. The manufacturing method for a semiconductor device according to claim 1,
wherein, in the step (c):
a fourth wire having a loop height lower than the second wire is mounted near the second wire on the standard suspension lead side of the second wire in the common lead region in order to electrically couple to a common lead.

3. The manufacturing method for a semiconductor device according to claim 2,
wherein, in the step (c):
the electrode pad for the semiconductor chip where no wire is coupled is mounted on the standard suspension lead side of the fourth wire in the common lead region.

4. The manufacturing method for a semiconductor device according to claim 3,
wherein, in the step (c):
the second wire is electrically coupled to the second lead at a position on the end nearest the standard suspension lead in the common lead region.

5. The manufacturing method for a semiconductor device according to claim 1,
wherein, in the step (c):
a fourth wire is mounted adjacent to the second wire in the common lead region, and also nearer the standard suspension lead than the second wire by setting a loop height of the fourth wire lower than the second wire, and the fourth wire is electrically coupled to the common lead.

6. The manufacturing method for a semiconductor device according to claim 2,
wherein, in the step (c):
a fifth wire having a loop height lower than the fourth wire is electrically coupled to the die pad.

7. The manufacturing method for a semiconductor device according to claim 1,
wherein the wire includes material whose main constituent is copper.

8. A semiconductor device comprising:
a die pad that includes a chip mounting surface;
a plurality of first leads that are mounted at the periphery of the die pad;
a plurality of second leads whose length is shorter than the respective first leads;
a common lead that is mounted between the die pad and the second leads as seen from a plan view;
a semiconductor chip that is mounted over the chip mounting surface of the die pad, and where a plurality of electrode pads are formed over the main surface of the chip;
a plurality of first wires that electrically couple the electrode pads of the semiconductor chip and the first leads;
a plurality of second wires or third wires that electrically couple the electrode pads of the semiconductor chip and the second leads;
a sealing body that seals a portion of the die pad, the common lead, the semiconductor chip, and the first, second, and third wires; and
a plurality of outer leads that are exposed from the sealing body,
wherein the second and the third wire are respectively formed to pass over the common lead,
wherein the loop height of the second wire is lower than the loop height of the third wire, and
wherein the heights of the common lead and the tips at the die pad side of each of the second leads, are the same.

9. The semiconductor device according to claim 8,
wherein the first, the second, and the third wire include a material whose main constituent is copper.

10. The semiconductor device according to claim 9,
wherein the rear side of the die pad is exposed at the rear side of the sealing body.
